(19) United States
(12) Patent Application Publication
(10) Pub. No.: US 2025/0277819 A1
(43) Pub. Date: Sep. 4, 2025

(54) TEST AND/OR MEASUREMENT INSTRUMENT, TEST SYSTEM AND METHOD OF MEASURING A RADIO FREQUENCY SIGNAL

(71) Applicant: Rohde & Schwarz GmbH & Co. KG, Muenchen (DE)

(72) Inventors: Matthias RUENGELER, Muenchen (DE); Florian RAMIAN, Muenchen (DE)

(21) Appl. No.: 18/594,438

(22) Filed: Mar. 4, 2024

(51) Int. Cl. G01R 13/02; G01R 13/34; G01R 31/28

(52) U.S. Cl. CPC G01R 13/0254; G01R 13/345; G01R 31/2822

(57) ABSTRACT

Embodiments of the present disclosure relate to a test and/or measurement instrument for measuring a radio frequency signal. The instrument has an input port, a measurement circuit configured to measure and digitize the radio frequency signal, thereby outputting a data stream. The instrument also has a trigger port configured to receive a periodic external trigger signal with periodically spaced trigger pulses. Further, the instrument has a trigger circuit configured to generate virtual trigger pulses based on the trigger pulses in the periodic external trigger signal. The instrument also includes an acquisition control circuit configured to receive the virtual trigger pulses. The acquisition control circuit is configured, upon reception of a virtual trigger pulse, to add a trigger information to the data stream generated by the measurement circuit.

### FIELD OF THE DISCLOSURE

Embodiments of the present disclosure relate to a test and/or measurement instrument for measuring a radio frequency signal. Further, embodiments of the present disclosure relate to a test system with an external trigger source and a test and/or measurement instrument. Moreover, embodiments of the present disclosure relate to a method of measuring a radio frequency signal.

### BACKGROUND

In the state of the art, test and/or measurement devices are known that process radio frequency (RF) signals, for instance capturing the radio frequency signals for further processing. One kind of radio frequency signals relate to repetitive signals that have several bursts. When processing such a repetitive signal, the test and/or measurement device generates a new individual trigger signal for each of the several bursts of the repetitive radio frequency signal, which starts the measurement of the radio frequency signal. Hence, a large number of trigger signals is generated. Consequently, the precision of the triggering is relevant for the overall precision of radio frequency signal processing.

Due to imperfections of the triggering, e.g. limited precision caused by finite steepness of edges of the trigger signals, a trigger signal is detected with certain deviations in time, which is called jitter. The respective trigger information, for instance a time stamp, is therefore generated with deviations in time, which makes the overall signal processing less accurate.

To overcome this issue, it is known in the state of the art to refine the trigger signals. The efforts associated therewith are however high, resulting in high costs and/or low performance.

Accordingly, there is a need for a test and/or measurement instrument as well as a method for measuring a radio frequency signal in an accurate manner, namely triggering on a radio frequency signal without jitter in order to increase the overall accuracy of the signal processing.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a test and/or measurement instrument for measuring a radio frequency signal. In an embodiment, the test and/or measurement instrument comprises an input port configured to receive the radio frequency signal to be measured. Further, the test and/or measurement instrument comprises a measurement circuit that is connected with the input port. The measurement circuit is configured to measure and digitize the radio frequency signal, thereby outputting a data stream comprising a plurality of samples. The test and/or measurement instrument also comprises a trigger port configured to receive a periodic external trigger signal with periodically spaced trigger pulses. Furthermore, the test and/or measurement instrument comprises a trigger circuit connected with the trigger port such that the periodic external trigger signal is forwarded from the trigger port to the trigger circuit. The trigger circuit is configured to generate virtual trigger pulses based on the trigger pulses in the periodic external trigger signal. The test and/or measurement instrument also comprises an acquisition control circuit that is connected with the trigger circuit. The acquisition control circuit is configured to receive the virtual trigger pulses generated by the trigger circuit. The acquisition control circuit, upon reception of a virtual trigger pulse, is configured to add a trigger information to the data stream generated by the measurement circuit.

Embodiments of the present disclosure also provide a method of measuring a radio frequency signal. In an embodiment, the method comprises receiving a radio frequency signal, measuring and digitizing the radio frequency signal, thereby outputting a data stream comprising a plurality of samples, receiving a periodic external trigger signal with periodically spaced trigger pulses, processing the periodic external trigger signal, generating virtual trigger pulses based on the trigger pulses in the periodic external trigger signal, and adding a trigger information to the data stream generated upon reception of a virtual trigger pulse.

The main idea is to use a periodic external trigger signal that has periodically spaced trigger pulses based on which virtual trigger pulses are generated which are used for enriching the data stream generated by the measurement circuit when processing the radio frequency signal. The periodic external trigger system, namely the periodically spaced trigger pulses, are processed by the test and/or measurement instrument in order to generate the virtual trigger pulses in order to ensure that the virtual trigger pulses do not have any jitter effects or limited precision. In other words, a time interval is used that defines the temporal spacing between the virtual trigger pulses such that all virtual trigger pulses do have the exact temporal relationship among each other. The temporal relationship or the temporal spacing is determined based on the trigger pulses in the periodic external trigger signal, which have been processed by the trigger circuit accordingly. The virtual trigger pulses are generated to correspond to a heartbeat trigger having a specific periodicity. In an embodiment, the virtual trigger pulses are generated such that they match to the radio frequency signal to be measured.

As indicated above, the periodic external trigger signal may have trigger pulses that are intended to be spaced from each other by a certain time range, for instance 5 ms. Due to finite edge steepness of the signal edges of the trigger pulses and other parasitic effects, the trigger pulses are not always exactly detected in accordance with the repetition pattern, e.g. every 5 ms. In an embodiment, the finite edge steepness and/or the parasitic effects cause(s) temporal deviations, namely jitter. For instance, the trigger pulses may only be detected with an accuracy of 0.1%, e.g. 0.1% earlier or later than intended, such that a certain temporal deviation takes place.

By generating the virtual trigger pulses, which follow the predetermined temporal spacing or temporal relationship, it can be ensured that these temporal deviations are compensated such that triggering can be performed with higher precision. The overall signal processing becomes more accurate due to the virtual trigger pulses that follow the predetermined temporal spacing or temporal relationship. The predetermined temporal spacing or temporal relationship however is not randomly set, but it is determined based on the trigger pulses in the periodic external trigger signal that is processed by the trigger circuit.

In an embodiment, the periodic external trigger signal comprises the trigger pulses that are periodically spaced according to an intended periodicity. The detected periodicity may however deviate from the intended one. When detecting the periodicities, e.g. with temporal deviations from the intended one, the rigger circuit is however enabled to determine/calculate the intended periodicity such that the virtual trigger pulses are generated so as to exactly follow the intended periodicity.

Generally, the virtual trigger pulses that are generated based on the trigger pulses in the periodic external trigger signal are more accurate with regard to periodicity compared to the trigger pulses in the periodic external trigger signal.

In an embodiment, the periodic external trigger signal may be an analog signal or a digital signal, for instance a transistor-transistor-logic (TTL) signal having a logic level.

In an embodiment, the measurement circuit is generally configured to process the radio frequency signal, wherein the radio frequency signal is measured and digitized such that a plurality of digitized samples is outputted by the measurement circuit. The plurality of samples are outputted in a successive manner, thereby generating a data stream, for example a continuous data stream. The measurement circuit may comprise an analog to digital converter (ADC) that is enabled to (continuously) generate the plurality of samples when digitizing the (analog) radio frequency signal. Besides the analog to digital converter, the measurement circuit may also comprise a filter and/or a mixer for processing the radio frequency signal, for example measuring and digitizing the radio frequency signal.

In an embodiment, the acquisition control circuit is enabled to receive the virtual trigger pulses from the trigger circuit and to process the virtual trigger pulses received in order to retrieve/derive trigger information thereof. The acquisition control circuit is also enabled to adapt the data contained in the data stream. In an embodiment, the acquisition control circuit is enabled to enrich the data contained in the data stream generated by the measurement circuit with the trigger information derived from the virtual trigger pulses received from the trigger circuit.

Generally, the trigger information added to the data stream may be added to at least one of the samples of the data stream or between neighbored samples of the data stream. In other words, the trigger information can be added to any point in time in the data stream. The point in time may be associated with a sample or not.

An aspect provides that the trigger circuit is configured, for example, to determine a periodicity of the trigger pulses in the periodic external trigger signal. In an embodiment, the trigger circuit is also configured to generate the virtual trigger pulses based on the determined periodicity of the trigger pulses in the periodic external trigger signal. Put differently, a periodicity of the trigger pulses in the periodic external trigger signal is determined, and wherein the virtual trigger pulses are generated based on the determined periodicity of the trigger pulses in the periodic external trigger signal.

As mentioned above, the periodic external trigger signal has several trigger pulses that are spaced in a periodic manner such that these trigger pulses follow a certain periodicity. In an ideal case, all trigger pulses follow the same periodicity, namely the intended periodicity. The periodicity of the trigger pulses in the periodic external trigger signal may however deviate due to finite edge steepness and other parasitic effects, causing jitter. In an embodiment, the trigger circuit may take several trigger pulses of the periodic external trigger signal, for example all trigger pulses (in a certain time span), into account in order to determine the intended periodicity, namely the underlying periodicity that the trigger pulses follow. Once the trigger circuit has determined the intended periodicity of the trigger pulses, the trigger circuit is enabled, for example, to generate the virtual trigger pulses based on the determined (intended) periodicity such that the virtual trigger pulses exactly follow the (intended) periodicity of the periodic external trigger signal. Consequently, the virtual trigger pulses do not have any temporal deviations from or limited precision with regard to the periodicity. Therefore, the virtual trigger pulses generated are more accurate than the periodically spaced trigger pulses that are processed by the trigger circuit, for example with regard to periodicity or deviations from the exact (intended) periodicity.

According to a certain embodiment, the trigger circuit comprises a detection sub-circuit that is configured the periodic external trigger signal received from the trigger port in order to detect appearance of the trigger pulses in the periodic external trigger signal. Thus, the detection sub-circuit is enabled to identify the trigger pulses in the periodic external trigger signal when the periodic external trigger signal is processed by the trigger circuit.

In an embodiment, the trigger circuit may also comprise a determination sub-circuit that is configured to determine a periodicity of the trigger pulses in the periodic external trigger signal. The determination sub-circuit may receive the respective information from the detection sub-circuit concerning the appearance of the trigger pulses, thereby being enabled to determine the periodicity of the trigger pulses. In an embodiment, the trigger pulses detected by the detection sub-circuit are processed in order to determine/calculate the periodicity. The detection sub-circuit and the determination sub-circuit may be (directly) connected with each other such that the detected trigger pulses, for example the information concerning the detected trigger pulses, is forwarded from the detection sub-circuit to the determination sub-circuit that processes the detected trigger pulses or the information concerning the detected trigger pulses accordingly in order to determine/calculate the periodicity. As discussed above, the periodicity determined/calculated by the determination sub-circuit corresponds to the intended periodicity of the periodic external trigger signal.

In an embodiment, the trigger circuit may further comprise a generation sub-circuit that is configured to generate the virtual trigger pulses based on the determined periodicity of the trigger pulses in the periodic external trigger signal. The generation sub-circuit may receive the information concerning the periodicity determined from the determination sub-circuit. Based on that the generation sub-circuit is capable of generating the virtual trigger pulses such that they follow exactly the periodicity determined, namely the intended periodicity of the periodic external trigger signal. This ensures that the virtual trigger pulses do have an exact temporal spacing from each other that is always the same. In other words, jitter or temporal deviations are compensated appropriately.

In an embodiment, the trigger circuit may comprise three different sub-circuits, namely the detection sub-circuit, the determination sub-circuit and the generation sub-circuit. However, two or all of these sub-circuits may also be established in a single circuit. For instance, the trigger circuit may comprise a single trigger detection module having circuitry that is configured to detect the appearance of the trigger pulses, to determine the periodicity of the detected trigger pulses, and to generate the virtual trigger pulses based on the determined periodicity. Moreover, the sub-circuits may be established on separate chips or all together on a single chip.

Another aspect provides that the trigger circuit is configured, for example, to determine the periodicity of the detected trigger pulses in the periodic external trigger signal based on a statistical evaluation. The periodicity is calculated by the determination sub-circuit of the trigger circuit, wherein the calculation is done based on a statistical evaluation of the detected trigger pulses. As mentioned before, the trigger pulses in the periodic external trigger signal follow a certain periodicity, namely the intended periodicity. Deviations from the intended periodicity may however take place such that the intended periodicity is not ensured for all trigger pulses in the periodic external trigger signal when processed by the trigger circuit.

In an embodiment, the trigger circuit, for example the determination sub-circuit, takes several trigger pulses into account, which have been detected by the trigger circuit, e.g. the detection sub-circuit, in order to statistically evaluate the trigger pulses, for example the periodicity associated therewith. The trigger circuit, for example the determination sub-circuit, is enabled to determine the (intended) periodicity of the periodic external trigger signal based on the statistical evaluation. The statistical evaluation may provide a probability of the intended periodicity of the trigger pulses in the periodic external trigger signal. Once the (intended) periodicity has been determined, the trigger circuit, for example the generation sub-circuit, may generate the virtual trigger pulses. The virtual trigger pulses are generated based on the determined periodicity, namely based on the statistical evaluation used for determining the periodicity, such that they exactly follow the determined periodicity, namely the intended periodicity of the periodic external trigger signal.

For instance, the trigger circuit is configured to generate a histogram of the trigger pulses in the periodic external trigger signal and to evaluate the histogram generated in order to determine the periodicity of the trigger pulses in the periodic external trigger signal. The histogram provides a distribution of the periodicities of each of the trigger pulses in the periodic external trigger signal, which are taken into account for determining the periodicity. The histogram obtained provides a statistical distribution of the periodicities, which can be evaluated in order to determine the (intended) periodicity. For instance, the statistical distribution corresponds to a Gaussian distribution. Therefore, the trigger circuit, for example the determination sub-circuit, is enabled to determine the intended periodicity of the detected trigger pulses in an accurate manner.

As indicated above, the trigger circuit is enabled to generate the virtual trigger pulses with a determined periodicity, namely the intended periodicity of the periodic external trigger signal. The virtual trigger pulses generated do have the exact periodicity. In other words, the virtual trigger pulses generated do have a perfect periodicity, as they are absolutely periodical, namely without jitter or temporal deviations.

A further aspect provides that the trigger circuit is configured, for example, to generate the virtual trigger pulses such that a time difference between neighbored virtual trigger pulses is the same for the virtual trigger pulses, thereby compensating for a non-zero rise time of a rising edge of trigger pulses. As mentioned before, the non-zero rise time of a rising edge of the trigger pulses in the periodic external trigger signal causes deviations from the intended (perfect) periodicity of the trigger pulses. Since the virtual trigger pulses are generated such that the time difference between neighbored virtual trigger pulses is always the same, any occurring deviations of the trigger pulses in the periodic external trigger signal can be compensated for. In an embodiment, a time difference between each of the virtual trigger pulses to its predecessor and/or successor is the same, as the virtual trigger pulses have exactly the same periodicity.

A further aspect provides that the trigger circuit is configured, for example, to add an offset to at least one specific virtual trigger pulse of the virtual trigger pulses such that the at least one specific virtual trigger pulse is temporarily aligned with one periodically spaced trigger pulse of the periodic external trigger signal. A time difference between neighbored virtual trigger pulses is the same for all virtual trigger pulses. Accordingly, it is ensured that the virtual trigger pulses generated follow the periodicity exactly. The offset is however used to temporarily align at least one of the virtual trigger pulses with one trigger pulse of the periodic external trigger signal. In other words, the virtual trigger pulses and the trigger pulses of the periodic external trigger signal are matched with each other at a certain point in time due to the offset added.

Generally, the trigger information may be a time stamp. Alternatively or additionally, the trigger information marks a sample or a point of time between two samples. The trigger information that is used to enrich the data stream obtained by the measurement circuit may additionally comprise a time stamp, namely a time stamp associated with a trigger event or temporal information of a trigger event. The trigger information added to the data stream may mark a certain sample of the data stream or a point of time between two samples. For instance, a trigger event may be associated with a point of time during which no data is received such that the trigger information added to the data stream may mark a point of time between two samples.

In an embodiment, the test and/or measurement instrument may also comprise a processing circuit that is configured to receive the data stream enriched with a trigger information. The processing circuit is connected with a node at which the data stream is enriched with the trigger information by the acquisition control circuit. The processing circuit is enabled to process both the samples of the data stream gathered by the measurement circuit and the trigger information provided by the trigger circuit. Since the acquisition control circuit is enabled to add the trigger information to the data stream at a certain point of time, the trigger information is not separately obtained by the processing circuit, but together with the data stream, as the data stream enriched with the trigger information is received and processed by the processing circuit.

In an embodiment, the processing circuit may be configured to generate graphical data based on at least parts of the data stream enriched with the trigger information, for instance the entire data stream enriched with the trigger information. The graphical data is capable of being displayed on a display, e.g. a display of the test and/or measurement instrument or an external display connected to the test and/or measurement instrument. Therefore, the processing circuit is enabled to generate data to be displayed on the display, for instance on a (graphical) user interface. A user can be informed about the data stream, namely the samples, together with the trigger information.

In an embodiment, the test and/or measurement instrument may also comprise a display that is connected with the processing circuit. The display is configured to display the graphical data generated. The test and/or measurement instrument can directly display the information associated with the graphical data generated in order to inform the user directly.

Alternatively, the graphical data generated by the processing circuit may be outputted such that the information associated with the graphical data is displayed on a separately formed display and/or at a different location.

For instance, the graphical data may relate to digital data that can be forwarded in a digital manner for being displayed on a separately formed display and/or at a different location.

Another aspect provides that the test and/or measurement instrument comprises, for example, a storage medium that is connected with the processing circuit. The processing circuit is configured to store at least parts of the data stream enriched with the trigger information in the storage medium. For instance, the entire data stream enriched with the trigger information is stored in the storage medium for further processing, e.g. post-processing. Storing at least parts of the data stream within the storage medium may depend on the trigger information obtained. In other words, the trigger information may be processed by the processing circuit in order to determine whether certain parts of the data stream are stored in the storage medium or not.

In a similar manner, generating the graphical data may also depend on the trigger information contained in the data stream enriched with the trigger information.

Generally speaking, the processing circuit may be enabled to process the trigger information in order to determine whether the data stream is (at least partly) stored and/or outputted, for instance as graphical data.

A further aspect provides that the test and/or measurement instrument comprises, for example, a digital interface output port that is configured to output at least parts of the data stream enriched with the trigger information. The digital interface output port may be used to directly output the data stream enriched with the trigger information at least partly for further processing, for instance for being processed by a separately formed device connected with the test and/or measurement instrument, e.g. an analyzer. As mentioned above, the digital interface output port may also be used for outputting the graphical data generated by the processing circuit such that the graphical data is outputted via the digital interface output port for being displayed on a separately formed display.

A further aspect provides that the test and/or measurement instrument comprises, for example, a virtual trigger output port that is configured to output the virtual trigger pulses. Thus, the virtual trigger pulses having the exact periodicity may be outputted via the virtual trigger output port, thereby ensuring that the virtual trigger pulses can be used by a separately formed device that is connected to the test and/or measurement instrument via the virtual trigger output port.

In an embodiment, the separately formed device may be connected to the virtual trigger output port and the digital interface output port simultaneously such that the separately formed device receives the data stream enriched with the trigger information at least partly and the virtual trigger pulses generated.

In an embodiment, the test and/or measurement instrument may have a housing with at least one outer surface at which the input port and the trigger port are located. Thus, cables, lines or similar can be connected with the respective ports located at the outer surface of the test and/or measurement instrument in order to forward the radio frequency signal to the measurement circuit and the periodic external trigger signal to the trigger circuit.

In a similar manner, the virtual trigger output port and/or the digital interface output port may also be located at the outer surface of the housing such that a separately formed device can be connected easily to the test and/or measurement instrument in order to obtain the data outputted via the virtual trigger output port and/or the digital interface output port.

In other words, the test and/or measurement instrument in some embodiments is a single device that has one housing that encompasses the measurement circuit, the trigger circuit as well as the acquisition control circuit. The processing circuit may also be encompassed via the housing.

In an embodiment, the storage medium may also be located within the housing of the test and/or measurement instrument. Alternatively, the storage medium may be located outside of the housing, for instance connected to the test and/or measurement instrument via a port, for instance a universal serial bus (USB) port.

In an embodiment, the display of the test and/or measurement instrument may be located at one of the outer surfaces of the housing.

Another aspect provides that the trigger circuit is configured, for example, to continuously observe the periodic external trigger signal and to adjust the virtual trigger pulses in case of observing a deviation of the periodic external trigger signal. Hence, the trigger circuit is enabled to identify a changing periodic external signal, for instance due to thermal drifts or due to another periodic external trigger signal forwarded to the trigger port. This changes can be identified due to continuously observing the trigger pulses of the periodic external trigger signal received, namely when determining the periodicity of the periodically spaced trigger pulses. Once the periodic external trigger signal changes, a respective periodicity also changes which is recognized by the trigger circuit that processes the periodically spaced trigger pulses of the changing/different periodic external trigger signal. Since the virtual trigger pulses are generated based on the periodicity determined for the changing/different periodic external trigger signal, the virtual trigger pulses are adjusted accordingly, for example in an automatic manner without any manual user input.

For instance, the trigger circuit is configured to adjust the virtual trigger pulses by changing a time difference between the virtual trigger pulses and/or by changing a linkage of at least one of the virtual trigger pulses to one of the periodically spaced trigger pulses of the periodic external trigger signal. In case it is recognized that the periodicity of the periodically spaced trigger pulses changes, the time difference between the virtual trigger pulses, namely the periodicity of the virtual trigger pulses, is adapted accordingly. In case it is recognized that a misalignment of the periodically spaced trigger pulses and the virtual trigger pulses occurs, the linkage is adapted, e.g. an offset, so as to temporarily match the virtual trigger pulses with the periodically spaced trigger pulses.

In other words, the parameters used for generating the virtual trigger pulses, namely the periodicity and the offset, are adjusted in case the trigger circuit identifies that the periodic external trigger signal deviates (over time).

Embodiments of the present disclosure also provide a test system with an external trigger source and a test and/or measurement instrument as described above. The external trigger source is configured to output the periodic external trigger signal with periodically spaced trigger pulses. The external trigger source is connected with a trigger port of the test and/or measurement instrument. Accordingly, the external trigger source provides the periodic external signal that is processed by the test and/or measurement instrument, for example the trigger circuit in order to determine the virtual trigger pulses.

In an embodiment, the test system may also comprise the separately formed device that is connected with the virtual trigger output port and/or the digital interface output port of the test and/or measurement instrument.

Generally, the virtual trigger pulses generated may be a virtual trigger signal, e.g. a heartbeat trigger signal due to its perfect periodicity. In an embodiment, an automatic trigger refinement for repetitive signals is obtained.

In an embodiment, the virtual trigger signal may also be used to periodically trigger the measurement circuit to capture the radio frequency signal, i.e. to digitize the RF signal.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a test system according to an embodiment of the present disclosure, which comprises a test and/or measurement instrument according to an embodiment of the present disclosure,

FIG. 2 schematically shows a flow-chart illustrating a representative method of measuring a radio frequency signal according to an embodiment of the present disclosure, and

FIG. 3 schematically shows a representative histogram of periodicities determined when statistically evaluating a periodic external trigger signal with periodically spaced trigger pulses by a trigger circuit of the test and/or measurement instrument according to an embodiment of the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

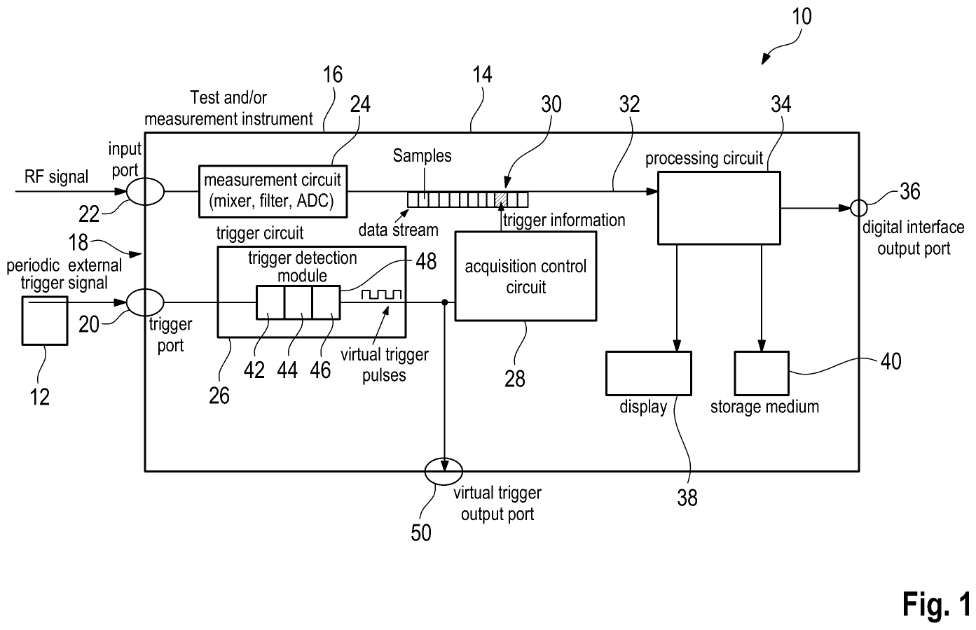

In FIG. 1, an example of a test system 10 is shown that comprises an external trigger source 12 that is configured to output a periodic external trigger signal with periodically spaced trigger pulses. As shown in the embodiment of FIG. 1, the test system 10 further comprises a test and/or measurement instrument 14 that has a housing 16 with an outer surface 18. At the outer surface 18 of the housing 16, a trigger port 20 is provided that is connected with the external trigger source 12 such that the trigger port 20 receives the periodic external trigger signal with the periodically spaced trigger pulses from the external trigger source 12.

In the embodiment shown, the test and/or measurement instrument 14 also has an input port 22 that is also located at the outer surface 18 of the housing 16. The test and/or measurement instrument 14 is configured to receive a radio frequency signal to be measured via the input port 22.

Still referring to embodiment of FIG. 1, the test and/or measurement instrument 14 further comprises a measurement circuit 24 that is connected with the input port 22 such that the measurement circuit 24 is enabled to receive the radio frequency signal inputted via the input port 22. In an embodiment, the measurement circuit 24 measures and digitizes the radio frequency signal, thereby outputting a data stream that comprises a plurality of samples, namely digitized samples. In the shown embodiment, the measurement circuit 24 comprises at least one mixer, at least one filter and at least one analog-to-digital converter (ADC) in order to process the radio frequency signal, for example to measure and to digitize the radio frequency signal.

In an embodiment, the test and/or measurement instrument 14 further comprises a trigger circuit 26 that is connected with the trigger port 20 such that the periodic external trigger signal with the periodically spaced trigger pulses is forwarded from the trigger port 20 to the trigger circuit 26. The trigger circuit 26 is generally configured to process the periodic external trigger signal in order to generate virtual trigger pulses based on the trigger pulses in the periodic external trigger signal, which will be described later in more detail. Accordingly, the trigger circuit 26 is capable of outputting the virtual trigger pulses.

In an embodiment, the test and/or measurement instrument 14 also comprises an acquisition control circuit 28 that is connected with the trigger circuit 26 in order to receive the virtual trigger pulses generated by the trigger circuit 26. The acquisition control circuit 28 is capable of processing the virtual trigger pulses generated by the trigger circuit 26 in order to derive trigger information from the virtual trigger pulses. The trigger information may relate to a time stamp. The acquisition control circuit 28 is also capable of adding the trigger information to the data stream generated by the measurement circuit 24 at a node 30. Generally, the trigger information is added to the data stream upon reception of a virtual trigger pulse. Hence, the acquisition control circuit 28 is connected with the node 30 that is also connected with the measurement circuit 24, as the data stream generated by the measurement circuit 24 is forwarded via a line 32 that comprises the node 30.

In general, the trigger information may be added to a sample of the data stream or to a point of time of the data stream, which is located between two samples of the data stream. In other words, the trigger information may mark a sample or a certain point of time that may also be located between two samples within the data stream. Accordingly, the data stream comprising the several samples is enriched with the trigger information by the acquisition control circuit 28.

In an embodiment, the data stream enriched with the trigger information is forwarded to a processing circuit 34 that is connected with the measurement circuit 24, for example via the line 32. The processing circuit 34 processes the samples of the data stream and the trigger information, namely the data stream enriched with the trigger information.

In an embodiment, the processing circuit 34 is generally configured to process the data stream dependent on the trigger information added. Hence, the processing circuit 34 is enabled to process the trigger information in order to gather information based on which the data stream is processed in a certain way. For instance, the processing circuit 34 may generate graphical data based on at least parts of the data stream enriched with the trigger information, wherein the graphical data can be displayed.

In an embodiment, the processing circuit 34 may also store at least parts of the data stream enriched with the trigger information when processing the data stream enriched with the trigger information. The processing circuit 34 may also (directly) output at least parts of the data stream enriched with the trigger information via a digital interface output port 36. Hence, the data stream may be processed by a separately formed device that is connected to the digital interface output port 36.

As mentioned above, the processing circuit 34 may take the trigger information into account in order to decide whether graphical data is generated based on at least parts of the data stream, at least parts of the data stream are stored and/or at least parts of the data stream are outputted (directly) via the digital interface output port 36. In an embodiment, the test and/or measurement instrument 14 may comprise a display 38 that is enabled to display the graphical data generated by the processing circuit 34. For instance, the graphical data associated with the data stream enriched with the trigger information may be displayed on a (graphical) user interface provided on the display 38.

In an embodiment, the test and/or measurement instrument 14 may comprise a storage medium 40 such that the processing circuit 44 is enabled to internally store the data stream enriched with the trigger information in the internal storage medium 40 at least partly. Alternatively or additionally, the data stream enriched with the trigger information is at least partly outputted via the digital interface output port 36, to which a separately formed device may be connected, for instance a separately formed display. Hence, graphical data generated by the processing circuit 34 may be outputted via the digital interface output port 36.

As mentioned above, the trigger circuit 26 is generally enabled to process the periodic external trigger signal in order to generate the virtual trigger pulses based on the trigger pulses in the periodic external trigger signal received by the trigger circuit 26.

Generally, the periodically spaced trigger pulses of the periodic external trigger signal follow a certain periodicity, namely an intended periodicity. Due to finite edge steepness of the signal edges of the trigger pulses of the periodic external trigger signal and other parasitic effects, the periodically spaced trigger pulses of the periodic external trigger signal are not always exactly detected in accordance with the repetition pattern associated with the (intended) periodicity. The finite edge steepness and/or the parasitic effects cause(s) temporal deviations of the detection of the periodically spaced trigger pulses. For instance, the trigger pulses may only be detected with an accuracy of 0.1%, namely 0.1% earlier or later than intended. Consequently, a certain temporal deviation would take place, namely jitter. This however would reduce the overall accuracy of the radio frequency signal processing.

In order to avoid jitter, namely the inaccuracy of the triggering, the trigger circuit 26 generates the virtual trigger pulses that exactly follow a certain periodicity, namely the intended periodicity of the periodic external trigger signal with periodically spaced trigger pulses. Put differently, the trigger circuit 26 determines a periodicity of the detected trigger pulses in the periodic external trigger signal, for example the intended periodicity. Based on the determined periodicity of the trigger pulses in the periodic external trigger signal, the trigger circuit 26 generates the virtual trigger pulses such that they exactly follow the determined periodicity.

In an embodiment, the trigger circuit 26 determines/calculates the periodicity based on a statistical evaluation of the trigger pulses in the periodic external trigger signal, for instance by a histogram that is used to generate a distribution of the periodicity of the detected trigger pulses. An example of this is schematically illustrated in FIG. 3.

Hence, the trigger circuit 26 is enabled to identify the periodicity with the highest frequency, namely which periodicity takes place most often. In FIG. 3, the specific periodicity is denoted by P since the periodicity P is most often determined (number #).

It can be assumed that this specific periodicity P corresponds to the intended periodicity of the periodic external trigger signal such that this specific periodicity obtained from the statistical evaluation, for example in the histogram, is used for generating the virtual trigger pulses. This means that a time difference between neighbored virtual trigger pulses is exactly the same for all virtual trigger pulses. Consequently, non-zero rise times of the rising edge of the trigger pulses can be contemplated appropriately by the virtual trigger pulses that follow the periodicity exactly. Accordingly, the trigger circuit 26 is generally enabled to detect an appearance of trigger pulses in the periodic external signal processed, to determine the periodicity of the detected trigger pulses, and to generate the virtual trigger pulses based on the determined periodicity.

In the shown embodiment, the trigger circuit 26 comprises respective sub-circuits that perform the tasks mentioned above. In an embodiment, the trigger circuit 26 may comprise a detection sub-circuit 42 that detects the appearance of the trigger pulses in the periodic external trigger signal inputted to the trigger circuit 26. The trigger circuit 26 may also comprise a determination sub-circuit 44 that determines the periodicity of the detected trigger pulses in the periodic external trigger signal. The determination sub-circuit 44 may process the trigger pulses detected by the detection sub-circuit 42 or information about the trigger pulses detected, which is forwarded to the determination sub-circuit 44 by the detection sub-circuit 42.

In an embodiment, the trigger circuit 26 may also comprise a generation sub-circuit 46 that is used to process the periodicity determined by the determination sub-circuit 44 in order to generate the virtual trigger pulses. As mentioned above, the virtual trigger pulses exactly follow the determined periodicity, e.g. the intended periodicity P of the trigger pulses in the periodic external trigger signal.

The respective sub-circuits 42, 44, 46 may be implemented on separate chips. However, two or all sub-circuits 42, 44, 46 may also be implemented on a single chip. In other words, the trigger circuit 26 may comprise a single trigger detection module 48 that includes circuitry encompassing all sub-circuits 42, 44, 46.

When generating the virtual trigger pulses, the trigger circuit 26, for example the generation sub-circuit 48, may also be enabled to add an offset to at least one specific virtual trigger pulse of the virtual trigger pulses. The offset added ensures to temporarily align the specific virtual trigger pulse with one of the several periodically spaced trigger pulses of the periodic external trigger signal. Hence, the virtual trigger pulses and the periodically spaced trigger pulses of the periodic external trigger signal match each other in at least one specific point of time.

Irrespective of the offset added, the virtual trigger pulses are generated such that the time difference between neighbored virtual trigger pulses is always the same for all virtual trigger pulses. In other words, the periodicity of all virtual trigger pulses is exactly the same.

In an embodiment, the trigger circuit 26 that receives the periodic external trigger signal is also enabled to continuously observe the periodic external trigger signal, for example the periodicity of the periodically spaced trigger pulses, in order to identify any deviation with regard to the periodicity. In case of observing a deviation of the periodic external trigger signal, for example the periodicity of the periodic external trigger signal, the trigger circuit 26 is enabled to adjust the virtual trigger pulses so as to follow the intended periodicity of the periodic external trigger signal. Thus, the test and/or measurement instrument 14 is enabled to automatically align itself with regard to the generation of the virtual trigger pulses to a changing periodic external trigger signal or another periodic external trigger signal inputted via the trigger port 20, for example a periodic external trigger signal having a different intended periodicity.

The adjustment of the virtual trigger pulses may relate to changing a time difference between the virtual trigger pulses and/or changing a linkage of at least one of the virtual trigger pulses to one of the periodically spaced trigger pulses of the periodic external trigger signal. As mentioned above, the virtual trigger pulses are generated by setting a periodicity and an offset such that the virtual trigger pulses generated exactly follow a calculated periodicity, namely the intended periodicity of the periodic external trigger signal, and are temporarily aligned with one of the periodically spaced trigger pulses at least once.

In an embodiment, the test and/or measurement instrument 14 also has a virtual trigger output port 50 via which the test and/or measurement instrument 14 is enabled to output the virtual trigger pulses generated by the trigger circuit 26. Hence, a digital trigger signal with virtual trigger pulses following exactly the determined periodicity can be provided via the virtual trigger output port 48 for processing by a separately formed device that is connected to the virtual trigger output port 50. The digital trigger signal relates to a virtual trigger signal that may also be called heartbeat trigger signal due to its exact periodicity.

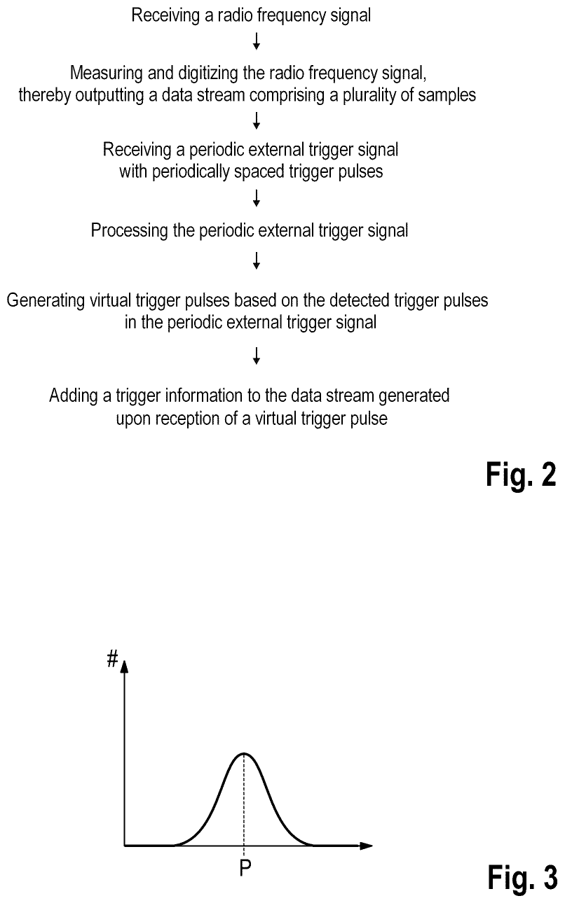

In FIG. 2, a representative method of measuring a radio frequency signal by the test and/or measurement instrument 14 is shown to which reference is made hereinafter.

A radio frequency signal is received via the input port 22 of the test and/or measurement instrument 14, which is forwarded to the measurement circuit 24 that measures and digitizes the radio frequency signal in order to output a continuous data stream that comprises a plurality of samples.

Besides the radio frequency signal, a periodic external trigger signal with periodically spaced trigger pulses is inputted to the test and/or measurement instrument 14, for example the trigger port 20, for instance from the external trigger source 12. The periodically spaced trigger pulses are intended to follow an intended periodicity. The periodic external trigger signal received via the trigger port 20 is forwarded to the trigger circuit 26 that processes the periodic external trigger signal.

As discussed above, the trigger circuit 26 may comprise several sub-circuits 42, 44, 46 that are enabled to detect the appearance of the trigger pulses in the periodic external trigger signal processed, to determine the periodicity of the detected trigger pulses in the periodic external trigger signal, and to generate virtual trigger pulses based on the determined periodicity of the trigger pulses in the periodic external trigger signal.

The periodicity determined relates to the intended periodicity of the periodically spaced trigger pulses even though the real periodicity detected for each of the periodically spaced trigger pulses may have deviations from the intended periodicity.

Accordingly, virtual trigger pulses are generated based on the detected trigger pulses in the periodic external trigger signal, wherein the virtual trigger pulses compensate effects causing the temporal deviations of the periodically spaced trigger pulses from the intended periodicity. In other words, the virtual trigger pulses exactly follow the intended periodicity.

The virtual trigger pulses are used for adding a trigger information to the data stream generated, wherein the trigger information is added by the acquisition control circuit 28 upon reception of a virtual trigger pulse from the trigger circuit 26. Since the virtual trigger pulses exactly follow the periodicity, the trigger information is added at the exact point of times, thereby improving the accuracy of radio frequency signal processing.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implemented the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components of the test and/or measurement instrument 14, the external trigger source 12, etc., referenced above include circuitry programmed to carry out one or more steps or actions of any of the methods disclosed herein. In some embodiments, one or more computer-readable media associated with or accessible by such circuitry contains computer readable instructions embodied thereon that, when executed by such circuitry, cause the component or circuity to perform one or more steps of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible to a computing device, such as processor circuitry, etc., or other circuity disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In some embodiments, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

In the detailed description herein, references to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. In addition, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. A test and/or measurement instrument for measuring a radio frequency signal, the test and/or measurement instrument comprising:
an input port configured to receive the radio frequency signal to be measured;
a measurement circuit connected with the input port, wherein the measurement circuit is configured to measure and digitize the radio frequency signal, thereby outputting a data stream comprising a plurality of samples;
a trigger port configured to receive a periodic external trigger signal with periodically spaced trigger pulses;
a trigger circuit connected with the trigger port such that the periodic external trigger signal is forwarded from the trigger port to the trigger circuit, and wherein the trigger circuit is configured to generate virtual trigger pulses based on the trigger pulses in the periodic external trigger signal;
an acquisition control circuit that is connected with the trigger circuit, wherein the acquisition control circuit is configured to receive the virtual trigger pulses generated by the trigger circuit, and wherein the acquisition control circuit, upon reception of a virtual trigger pulse, is configured to add a trigger information to the data stream generated by the measurement circuit.

2. The test and/or measurement instrument according to claim 1, wherein the trigger circuit is configured to determine a periodicity of the trigger pulses in the periodic external trigger signal, and wherein the trigger circuit is configured to generate the virtual trigger pulses based on the determined periodicity of the trigger pulses in the periodic external trigger signal.

3. The test and/or measurement instrument according to claim 2, wherein the trigger circuit comprises:
a detection sub-circuit that is configured to process the periodic external trigger signal received from the trigger port in order to detect appearance of the trigger pulses in the periodic external trigger signal,
a determination sub-circuit that is configured to determine the periodicity of the trigger pulses in the periodic external trigger signal, and/or
a generation sub-circuit that is configured to generate the virtual trigger pulses based on the determined periodicity of the trigger pulses in the periodic external trigger signal.

4. The test and/or measurement instrument according to claim 2, wherein the trigger circuit is configured to determine the periodicity of the trigger pulses in the periodic external trigger signal based on a statistical evaluation.

5. The test and/or measurement instrument according to claim 2, wherein the trigger circuit is configured to generate a histogram of the trigger pulses in the periodic external trigger signal and to evaluate the histogram generated in order to determine the periodicity of the trigger pulses in the periodic external trigger signal.

6. The test and/or measurement instrument according to claim 1, wherein the trigger circuit is configured to generate the virtual trigger pulses such that a time difference between neighbored virtual trigger pulses is the same for the virtual trigger pulses, thereby compensating for a non-zero rise time of a rising edge of trigger pulses.

7. The test and/or measurement instrument according to claim 1, wherein the trigger circuit is configured to add an offset to at least one specific virtual trigger pulse of the virtual trigger pulses such that the at least one specific virtual trigger pulse is temporally aligned with one periodically spaced trigger pulse of the periodic external trigger signal, and wherein a time difference between neighbored virtual trigger pulses is the same for the virtual trigger pulses.

8. The test and/or measurement instrument according to claim 1, wherein the trigger information is a time stamp and/or wherein the trigger information marks a sample or a point of time between two samples.

9. The test and/or measurement instrument according to claim 1, further comprising a processing circuit that is configured to receive the data stream enriched with the trigger information.

10. The test and/or measurement instrument according to claim 9, wherein the processing circuit is configured to generate graphical data based on at least parts of the data stream enriched with the trigger information, and wherein the graphical data is capable of being displayed on a display.

11. The test and/or measurement instrument according to claim 10, further comprising a display that is connected with the processing circuit, and wherein the display is configured to display the graphical data generated.

12. The test and/or measurement instrument according to claim 9, further comprising a storage medium that is connected with the processing circuit, and wherein the processing circuit is configured to store at least parts of the data stream enriched with the trigger information in the storage medium.

13. The test and/or measurement instrument according to claim 1, further comprising a digital interface output port that is configured to output at least parts of the data stream enriched with the trigger information.

14. The test and/or measurement instrument according to claim 1, further comprising a virtual trigger output port that is configured to output the virtual trigger pulses.

15. The test and/or measurement instrument according to claim 1, further comprising a housing with at least one outer surface at which the input port and the trigger port are located.

16. The test and/or measurement instrument according to claim 1, wherein the trigger circuit is configured to continuously observe the periodic external trigger signal and to adjust the virtual trigger pulses in case of observing a deviation of the periodic external trigger signal.

17. The test and/or measurement instrument according to claim 16, wherein the trigger circuit is configured to adjust the virtual trigger pulses by changing a time difference between the virtual trigger pulses and/or by changing a linkage of at least one of the virtual trigger pulses to one of the periodically spaced trigger pulses of the periodic external trigger signal.

18. A test system with an external trigger source and a test and/or measurement instrument according to claim 1, wherein the external trigger source is configured to output a periodic external trigger signal with periodically spaced trigger pulses, and wherein the external trigger source is connected with the trigger port of the test and/or measurement instrument.

19. A method of measuring a radio frequency signal, the method comprising:
receiving a radio frequency signal;
measuring and digitizing the radio frequency signal, thereby outputting a data stream comprising a plurality of samples;
receiving a periodic external trigger signal with periodically spaced trigger pulses;
processing the periodic external trigger signal;
generating virtual trigger pulses based on the trigger pulses in the periodic external trigger signal; and
adding a trigger information to the data stream generated upon reception of a virtual trigger pulse.

20. The method according to claim 19, wherein a periodicity of the trigger pulses in the periodic external trigger signal is determined, and wherein the virtual trigger pulses are generated based on the determined periodicity of the trigger pulses in the periodic external trigger signal.
